(19) United States
(12) Patent Application Publication
(10) Pub. No.: US 2026/0266883 A1
(43) Pub. Date: Sep. 10, 2026

(54) ALL-OPTICAL RF SIMULTANEOUS I/Q PHASE READOUT IN A QUANTUM ANTENNA

(71) Applicants: SRI International, Menlo Park, CA (US); Government of the United States of America, as represented by the Secretary of Commerce, Gaithersburg, MD (US)

(72) Inventors: Samuel Berweger, Boulder, CO (US); Christopher L Holloway, Boulder, CO (US); Alexandra Brae Artusio-Glimpse, Boulder, CO (US); Andrew Peter Rotunno, Broomfield, CO (US); Nikunjkumar Prajapati, Lafayette, CO (US); Matthew Simons, Lafayette, CO (US); Kaitlin Moore, Skillman, NJ (US); Joseph Christesen, Longmont, CO (US)

(21) Appl. No.: 19/128,759

(22) PCT Filed: Nov. 9, 2023
(86) PCT No.: PCT/US2023/079261

§ 371 Date: May 9, 2025

Related U.S. Application Data
(60) Provisional application No. 63/383,448, filed on Nov. 11, 2022.

(51) Int. Cl. G01R 29/08; H01Q 15/02; H04B 10/61

(52) U.S. Cl. CPC G01R 29/0878; H04B 10/61; H01Q 15/02

(57) ABSTRACT

A method includes detecting, by an atomic receiver, incident electromagnetic (EM) radiation comprising an incident EM frequency and an incident EM phase, and generating, by the atomic receiver and based on the detected incident EM radiation, a signal indicative of the incident EM phase, wherein the atomic receiver generates the signal without the use of a local oscillator.

This application claims the benefit of U.S. Provisional Patent Application 63/383,448, filed Nov. 11, 2022, the entire content of which is incorporated herein by reference.

### GOVERNMENT RIGHTS

This invention was made with government support under contract number HR001121C0141 awarded by the Defense Advanced Research Projects Agency (DARPA). The Government has certain rights to this invention.

### TECHNICAL FIELD

This disclosure generally relates to electromagnetic radiation sensors.

### SUMMARY

In general, systems and techniques are described for a sensing system for simultaneous in-phase and quadrature (I/Q) readout of sensed electromagnetic radiation for a broad range of radio frequencies. The sensing system can operate without the use of a radio frequency (RF) local oscillator and enable determination of a full 0-degree to 360-degree range of phase value of the sensed radio frequencies. Systems and techniques disclosed herein may include, in examples, a quantum antenna and/or quantum sensor and preparation of alkali atoms to be in a quantum state having a high angular momentum, e.g., exciting alkali atoms such that one or more electrons of the atoms have a relatively high orbital angular momentum quantum number.

In one example, this disclosure describes a method including: detecting, by an atomic receiver, incident electromagnetic (EM) radiation comprising an incident EM frequency and an incident EM phase; and generating, by the atomic receiver and based on the detected incident EM radiation, a signal indicative of the incident EM phase, wherein the atomic receiver generates the signal without the use of a local oscillator.

In another example, this disclosure describes a sensing system including: an atomic receiver configured to detect an incident EM phase of incident electromagnetic (EM) radiation without the use of a local oscillator.

In another example, this disclosure describes a sensing system including: a vapor cell including a plurality of alkali atoms; a preparation system configured to direct optical electromagnetic (EM) radiation of a plurality of optical frequencies into the vapor cell and incident on the plurality of alkali atoms, the preparation system includes a probe electromagnetic (EM) radiation having a probe frequency; a first coupling EM radiation having a first coupling frequency and a first coupling phase; and a second coupling EM radiation having a second coupling frequency and a second coupling phase, wherein each of the probe frequency, the first coupling frequency, and the second coupling frequency comprises at least one of an ultraviolet (UV), a visible, or a near-infrared (NIR) frequency, and wherein the EM radiation of the plurality of optical frequencies is configured to excite the plurality of alkali atoms from a first quantum state to a plurality of Rydberg states comprising a quantum interferometric loop; and a detector configured to detect an electrically induced transparency (EIT) of the plurality of alkali atoms upon excitation of the alkali atoms by incident EM radiation comprising an incident EM frequency and an incident EM phase, wherein the EIT is indicative of the incident EM phase.

The details of one or more examples of the disclosure are set forth in the accompanying drawings, and in the description below. Other features, objects, and advantages of the disclosure will be apparent from the description and drawings, and from the claims.

### BRIEF DESCRIPTION OF DRAWINGS

FIG. 1 is a cross-sectional block diagram illustrating an example electromagnetic (EM) radiation sensing system, in accordance with the techniques of the disclosure.

FIG. 2 is an illustration of an example energy diagram of an alkali atom including at least one Rydberg state, in accordance with the techniques of the disclosure.

FIG. 3 is a cross-sectional block diagram illustrating an example EM radiation sensing system including a probe beam detection system, in accordance with the techniques of the disclosure.

FIG. 4A is a diagram illustrating another example EM radiation sensor utilizing a balanced probe beam detection system, in accordance with the techniques of the disclosure.

FIG. 4B is a plot illustrating an example frequency spectrum of coupling radiation used in the balanced probe beam detection system of the system of FIG. 4A, in accordance with the techniques of the disclosure.

FIG. 4C is an illustration of an example EIT energy diagram ladder and Rydberg states illustrating a quantum interference loop corresponding to the balanced probe beam detection system of FIG. 4A, in accordance with the techniques of the disclosure.

FIG. 5A is a heatmap illustrating an example signal probe EM radiation of the EM radiation sensor of FIG. 4A as a function of coupling EM radiation detuning and control photon phase, in accordance with the techniques of the disclosure.

FIG. 5B is a plot illustrating the example signal probe EM radiation of the EM radiation sensor of FIG. 4A as a function of coupling EM radiation detuning at the two phases indicated in FIG. 5A, in accordance with the techniques of the disclosure.

FIG. 5C is a plot illustrating the example signal probe EM radiation of the EM radiation sensor of FIG. 4A as a function of control photon phase at the three coupling EM radiation detuning frequencies indicated in FIG. 5A, in accordance with the techniques of the disclosure.

FIG. 6A is a plot of an example phase-dependent in-phase (I) lock-in mixer signal as a function of coupling EM radiation detuning, in accordance with the techniques of the disclosure.

FIG. 6B is a plot of an example phase-dependent evolution of the in-phase (I) and out-of-phase (quadrature Q) signals of FIG. 6A at a particular detuning, in accordance with the techniques of the disclosure.

FIG. 7A is plot of an example lock-in output of a simulated QPSK signal with a symbol rate of 800 Hz, in accordance with the techniques of the disclosure.

FIG. 7B is polar plot constellation diagram of the phases of FIG. 7A, in accordance with the techniques of the disclosure.

FIG. 8 is a flowchart of an example method of simultaneous I/Q phase readout, in accordance with the techniques of the disclosure.

FIG. 9 is an illustration of an example optical phase readout system including an example dual probe system for simultaneous I/Q phase readout, in accordance with the techniques of the disclosure.

FIG. 10 is a pair of plots of example demodulated I/Q signals corresponding to the fractional transmission of the dual probe beams of the dual probe system of FIG. 9, in accordance with the techniques of the disclosure.

FIG. 11 is a plot of an I/Q diagram of the demodulated I/Q signals of FIG. 10, in accordance with the techniques of the disclosure.

FIG. 12 is a plot of an example probe signal of a dual probe system for simultaneous I/Q phase readout, in accordance with the techniques of the disclosure.

FIG. 13 is a plot of example diagram of simultaneous I/Q phase readout, with I and Q being measured by orthogonally-polarized preparation and readout beams, in accordance with the techniques of the disclosure.

### DETAILED DESCRIPTION

Detecting low-frequency electric fields and/or electromagnetic (EM) radiation, e.g., incident EM radiation, is typically done with antenna structures. As the signal of interest (e.g., incident EM radiation) moves to lower frequencies, typical antenna structures get physically larger due to efficient antenna designs being linked to the wavelength of the signal of interest. This wavelength can get quite large as the frequencies move from the gigahertz (GHz) regime (approximately 30 cm) to the megahertz (MHz) regime, e.g., 10 MHz (30 meters). Limiting the size of classical antennas, for linear time-invariant systems, limits the available information bandwidth, a known phenomenon now known as the Chu-Harrington limit.

“Quantum sensing” may use Rydberg atoms in millimeter-to-centimeter-scale vacuum cells to sense low frequency electric fields and/or EM radiation, breaking the Chu limit, and offering an efficient way to sense EM radiation in the MHz-GHz frequency range with a small footprint system. Rydberg atoms are highly excited atoms, where the difference in a quantum number (e.g., a principal quantum number, an orbital angular momentum quantum number which may be indicative of a transition between excitation levels) may be used to detect resonant frequencies, and a shift in a measured energy level is used to detect off-resonant frequencies. On-resonant detection is orders of magnitude more sensitive than off-resonant detection. Typical Rydberg experiments operate in the 10 GHz-100 GHz, as this is where the most accessible transitions lie (i.e., principal quantum number, n=10 s-100 s). Scaling quantum sensing systems using Rydberg atoms to the megahertz and/or tens of megahertz range implies principal quantum numbers much greater than 100 (n>>100), or in some cases (n>>200), for resonant detection and may not traditionally be feasible. At such high principal quantum numbers, the excited atoms may be very easily perturbed by external fields and atom-particle interactions, which can obscure the desired electric field and/or EM radiation detection.

In some examples described herein, systems, devices, and methods may detect electromagnetic (EM) radiation having frequencies in the megahertz (MHz) and gigahertz (GHz) ranges with a relatively small sized sensing element, e.g., a sensing volume that is less than the wavelength of the incoming EM radiation being sensed/detected (e.g., the signal-of-interest). In some examples, the techniques and sensors provide a high sensitivity to incident EM radiation having relatively low frequencies. In some examples, a vapor cell may operate as a transducer to convert EM radiation having frequencies in a first range to an EM radiation response having frequencies in a second range. In some examples, compared to direct detection of EM radiation in the first range, electromagnetic radiation in the second frequency range may be more discernable, have a higher signal-to-noise (SNR) ratio, may be less expensive to detect, may be detectable with a smaller and/or lighter apparatus, and have a higher sensitivity.

In some examples, a vapor cell array may include a plurality of vapor cells including alkali atoms. The alkali atoms may be prepared in a Rydberg state in which the alkali atoms are excited such that one or more electrons have a relatively low principal quantum number, e.g., n less than 200 (n≤200), while having a relatively high orbital angular momentum quantum number, e.g., 1≥3. In some examples, preparation of the alkali atoms in a Rydberg state with a relatively low principal quantum number and a relatively high orbital angular momentum may be done via multiple excitations, e.g., via multiple quantum levels via relatively lower energy excitations.

For example, techniques may include preparing a vapor of alkali atoms via multiple excitation levels (e.g., three or more excitation levels) to a Rydberg state having a relatively low principal number (n≤200) and a relatively high orbital angular momentum quantum number (1≥3). The atoms may be prepared to such a Rydberg state via multiple lower-energy transitions, e.g., at least two transitions to access a Rydberg state. Rydberg states having a low principal quantum number are advantageous over Rydberg states with higher principal quantum numbers because an atom in a Rydberg state having a low principal quantum number may reduce noise (e.g., may not be as easily perturbed by external fields and/or atom-particle interactions) relative to an atom in a Rydberg state having a high quantum number. A Rydberg state having a high angular momentum is advantageous because it has a higher sensitivity to lower frequencies (e.g., <10 MHz-1 GHz) with a reduced atom size due to the relatively lower principal quantum number

A sensor may include a vapor cell including a vapor of alkali atoms and a system configured to direct EM radiation of one or more frequencies into the vapor cell and incident on the vapor of alkali atoms, e.g., separate EM radiations, or beams, having the same or different frequencies. The EM radiation, or beams, of one or more frequencies may be configured to correspond to resonant or near-resonant transitions of the alkali atoms between a first quantum state (or energy state) and a second quantum state, e.g., a Rydberg state.

In some examples, the EM radiation of one or more frequencies may include two frequencies different from each other and each configured to be resonant or near-resonant with two different quantum states separated by at least one radiofrequency transition. In some examples, the EM radiation of one or more frequencies may include multiple frequencies configured to be resonant or near-resonant between multiple intermediate quantum states of the alkali atoms between the first quantum state and the second (Rydberg) quantum state. In other words, the EM radiation may include multiple beams having frequencies configured to be resonant or near-resonant with one or more intermediate quantum states in a “chain” from the first quantum state to the Rydberg quantum state. The alkali atoms prepared in the second quantum state, e.g., the Rydberg state, may have an orbital angular momentum quantum number that is equal to the number of quanta (photons) used to prepare the alkali atoms, e.g., from the first to the second quantum states via one or more intermediate quantum states. The sensor may include a detector configured to detect a response of the alkali atoms to incident EM radiation after the alkali atoms are prepared in the Rydberg state, e.g., from the first quantum state to the second quantum state.

In a hydrogen atom, states having same quantum number n but different orbital angular momentum l are energetically degenerate and form a manifold of states. In a non-hydrogenic alkali atom such as rubidium, the low angular momentum l states are energetically depressed from the hydrogenic manifold of higher angular momentum l states, e.g., due to the core penetration or core polarization of the electron. As angular momentum l increases within a manifold of states, adjacent energy levels become closer together until becoming energetically unresolved, typically around angular momentum l numbers of about 6-7 in rubidium. For interrogation of atomic states, angular momentum quanta is preserved along with energy, and so not only does the energy of applied photons sum up to the resonance condition of a transition, but the number of photons is also equal to the number of angular momentum steps taken in the transition.

In accordance with the techniques, systems, devices, and/or sensors disclosed herein, a multi-photon interrogation system may prepare atoms in Rydberg states, including high-angular momentum Rydberg states near a manifold of states. The techniques, systems, devices, and/or sensors may provide access to detecting a very large, and in some examples a continuous, range of RF frequencies, e.g., a full spectrum of RF frequencies 10 MHz to 1 THz.”

For example, preparation of atoms in a high-angular-momentum Rydberg state may provide the correct conditions to implement an all-optical phase-readout tunable across the entire frequency range. In some examples, independent probe polarization states are used to separate amplitude information from phase information for true dual-channel I/Q demodulation to provide a data rate and capability to enable all-optical arbitrary waveform demodulation without needing to use a RF local oscillator (LO) with the receiver element, e.g., without an internal or external RF LO. In some examples, the techniques, systems, devices, and/or sensors disclosed herein may be configured to receive amplitude and phase-modulated waveforms, with the frequency agility to accommodate advanced frequency hopping spread spectrum signals. Additionally, techniques, systems, devices, and/or sensors may allow for a generalized all-optical amplitude and phase readout methodology for arbitrary signal demodulation, and optical delivery of the LO (e.g., as opposed to an RF LO) without the need for directly applied RF fields in, or to, the vapor cell may provide for phase-sensitive detection of waveforms without RF emissions and without RF crosstalk in future angle-of-arrival arrays.

RF phase detection using quantum antennas may implement heterodyne systems in which the RF signal is interfered with a well-known local oscillator (LO) delivered via an RF feedthrough (comprising metals and/or metallic components) integrated into a receiver element. Such heterodyne systems add a field sensitivity gain proportional to the square root of the ratio of the local oscillator current to the signal current (e.g., \sqrt{I_LO/I_SIG}), but does not have a low RF profile and or tolerance as it relies on RF emissions and requires bulk metal electrodes in the vicinity of the sensing vapor cell, as well as RF cables routed to the sensing element.

Other RF phase detection systems introduce optical phase readout in quantum antennas for a very narrow set of conditions. Such systems may include providing two coupling paths for electromagnetic induced transparency (EIT), requiring two degenerate RF field photons to complete the quantum interference loop, and the probe spectrum depends on the phase difference between the optical coupling field and the RF field. When the two coupling paths are both on resonance and the RF field is detuned from resonance, the resulting Autler-Townes (AT) peaks are 90 degrees out of phase, which is equivalent to reading out only the magnitudes of I and Q. At a given optical phase, the AT peaks are representative of homodyne down-conversion at 0 degrees and 90 degrees. The strength of each AT peak at a fixed optical phase may then be monitored, which may be equivalent to reading out the I and Q baseband modulation of the RF signal, but may difficult to achieve in practice. The atoms in this configuration may act as a direct-conversion receiver, with the magnitude of the I and Q output in the probe transmission at the two coupler frequencies for the AT peaks. However, simultaneously monitoring the probe transmission at the two AT peak coupler frequencies is challenging. For example, to distinguish these two AT peaks with a single probe beam, the coupling frequency is modulated at a rate low enough for the atoms to respond, thereby limiting the RF modulation frequency. Additionally, the AT splitting must be large enough to resolve, which severely limits the sensitivity. Also, due to requiring a two-photon RF transition, this system may be suitable for only a narrow set of Rydberg levels and/or states (e.g., RF resonances) and may not be generalizable to a broad set of Rydberg levels and/or states (or RF resonances).

In examples of the present disclosure, a sensor and sensing techniques include an all-optical architecture for simultaneous in-phase and quadrature (I/Q) readout of sensed electromagnetic radiation for a broad range of radio frequencies. As described herein, “I/Q,” “I/Q signal”, or “I/Q signals” may refer to an in-phase signal and a quadrature signal. In some examples, the sensor may be a quantum antenna and/or quantum sensor and the techniques may include the preparation of alkali atoms to be in a quantum state having a high angular momentum, e.g., excited such that one or more electrons of the atoms have a relatively high orbital angular momentum quantum number. When prepared, independent probe polarization states may be used to separate amplitude from phase information (e.g., from signals that may be output by the prepared alkali atoms in response to interactions with electromagnetic radiation of interest) in order to obtain dual-channel I/Q demodulation. The I/Q demodulation provides the data rate and capability for all-optical demodulation of arbitrary (e.g., in any form) waveforms, e.g., without the application of radiofrequency (RF) energy directly to the receive element(s) of the sensor.

In some examples, the sensors and techniques may be configured to receive phase-shift-keyed signals (e.g., a fundamental signal class for global positioning systems) by sensing the phase of incoming RF fields, e.g., RF fields received by, incident on, and/or applied to a quantum antenna and/or sensor. For example, all-optical techniques disclosed herein may provide a local oscillator (LO) directly to a spatial region of photon-atom overlap in the sense element of the antenna (e.g., a spatial region in which prepared alkali atoms in a quantum sensor and photons of incoming RF radiation to be detected are co-located at the same time), without RF emissions (e.g., RF emissions that may be used for preparing the alkali atoms and that may be distinct or different from the RF radiation of interest being detected). In some examples, the all-optical techniques disclosed herein additionally do not require any bulk metal electrodes in the vicinity of the sensing vapor cell of the quantum sensor. Reducing the additional elements required for the sensor head may provide improved and/or optimized RF radiation transparency, e.g., an improved clear aperture of the sensor for which to receive the RF radiation of interest within a vapor cell to interact with the prepared alkali atoms and be detected. The all-optical system also provides easy component integration (e.g., reduced complexity) via having only optical fiber connections (rather than additional electrical connections or RF waveguiding components), and may provide an element (e.g., sensor element) with a reduced and/or minimized size.

The sensors and techniques described herein may provide the LO directly to the spatial region of photon-atom overlap in the sense element of the antenna, without RF emissions, and may not require any bulk metal electrodes in the vicinity of the sensing vapor cell. Reducing the additional elements required for the sensor head may allow for improved and/or optimized RF transparency, and improved signal sensing. The all-optical techniques disclosed herein may also provide improved (e.g., simplified and/or easier) component integration via using only optical fiber connections and a reduced sensing element size, which may provide improved sensing resolution (e.g., when used as a single sensor or for an array of such sensors).

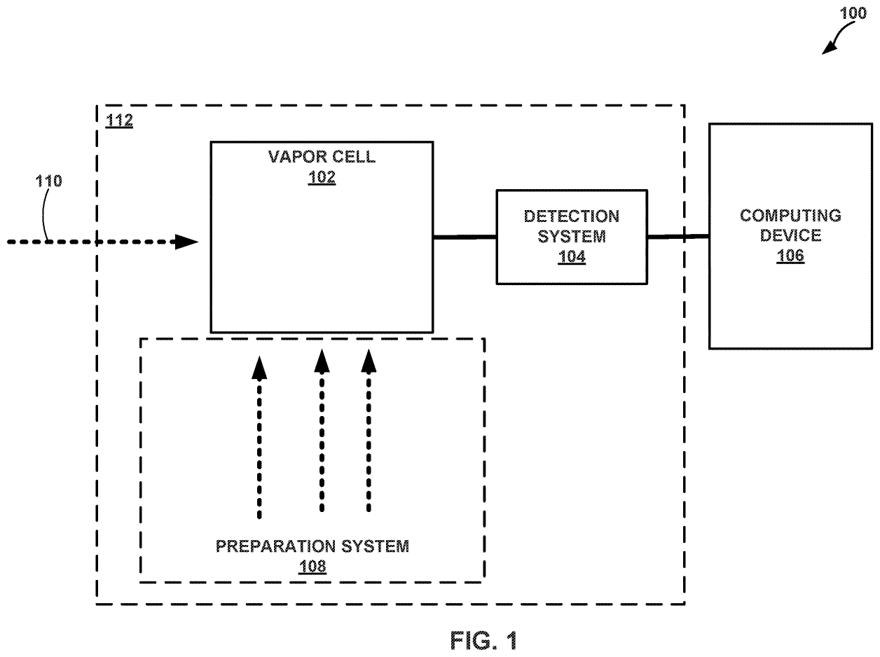

FIG. 1 is a cross-sectional block diagram illustrating an example EM radiation sensing system 100, in accordance with the techniques of the disclosure. In the example shown, sensing system 100 includes sensor 112 and computing device 106. Sensor 112 includes a vapor cell 102, a detection system 104, and a preparation system 108. EM radiation sensing system 100 and/or sensor 112 may be configured to sense incident EM radiation 110.

Vapor cell 102 may include a vapor of atoms, for example, alkali atoms. In some examples, vapor cell 102 may be configured to be a transducer to convert incident EM radiation 110, e.g., electromagnetic radiation having frequencies in a first frequency range, to electromagnetic radiation having frequencies in a second range or to an ionization state of the atoms in the vapor cell. For example, each vapor cell 102 may transduce, or convert, incident EM radiation 110 having frequencies in the MHz-THz frequency range to optical/visible light frequencies.

Detection system 104 may include one or more detectors, circuits, meters, and the like, configured to detect a response of the alkali atoms to incident EM radiation after the alkali atoms are prepared in the Rydberg state. For example, detection system 104 may include an optical detector configured to detect an amount of EM probe light and capture an absorption spectrum of the alkali atoms as a function of detuning of the frequency of the EM probe beam frequency and indicating/quantifying electromagnetic induced transparency (EIT) of the vapor of alkali atoms. Detection system 104 may be configured to detect response of the alkali atoms, prepared in a Rydberg state, to incident EM radiation and convert the detected response to one or more signals, e.g., analog and/or digital signals.

Computing device 106 may be configured to receive analog and/or digital signals from detection system 104. For example, computing device 106 may be configured to process and record and/or store received signals from detection system 104, and may be configured to store and/or output raw and/or processed data indicative of incident EM radiation 110, e.g., an amount and/or spectral content of EM radiation 110. Computing device 106 may include one or more processors, memory, and interface components.

For example, the one or more processors of computing device 106 may include any one or more of processing circuitry, a microprocessor, a controller, a digital signal processor (DSP), an application specific integrated circuit (ASIC), a field-programmable gate array (FPGA), or equivalent discrete or integrated logic circuitry. The functions attributed to processors described herein may be provided by processing circuitry of a hardware device, e.g., as supported by software and/or firmware.

In some examples, memory of computing device 106 may include any volatile or non-volatile media, such as a random-access memory (RAM), read only memory (ROM), non-volatile RAM (NVRAM), electrically erasable programmable ROM (EEPROM), flash memory, and the like. The memory may be a storage device or other non-transitory medium and may be used by processing circuitry to, for example, store information related to sensing system 100, such as information relating to vapor cell 102, detection system 104, preparation system 108, and incident EM radiation 110. In some examples, the memory may store information or previously received data from detection system 104 for later retrieval. In some examples, the memory may store settings, determined values, and/or calculated values for later retrieval.

In some examples, interface components of computing device 106 may include output devices, such as a display, sound card, video graphics adapter card, speaker, presence-sensitive screen, one or more USB interfaces, video and/or audio output interfaces, or any other type of device capable of generating tactile, audio, video, or other output. A display device may use technologies including liquid crystal displays (LCD), quantum dot display, dot matrix displays, light emitting diode (LED) displays, organic light-emitting diode (OLED) displays, cathode ray tube (CRT) displays, e-ink, or monochrome, color, or any other type of display capable of generating tactile, audio, and/or visual output.

In some examples, computing device 106 may be integrated with sensing system 100, e.g., integrated with one or more of vapor cell 102, detection system 104, and preparation system 108. In other examples, computing device 106 may be an external device, e.g., a computing device separate from sensing system 100 and configured to communicate with sensing system 100.

Preparation system 108 may include one or more EM radiation frequencies configured to prepare alkali atoms within vapor cell 102 to a second, higher quantum energy state, e.g., a Rydberg state, from a first quantum energy state, which may be a ground state of the vapor of alkali atoms. In some examples, preparation system 108 may include any hardware suitable for preparing the atoms to be in the Rydberg state. For example, preparation system may include a plurality of EM radiation sources and physical/optical elements configured to direct EM radiation from the one or more EM radiation sources. In some examples, preparation system 108 may be all-optical, e.g., including EM radiation sources may include optical sources such as a lasers, light emitting diodes, incandescent sources, fluorescent sources, or the like. Physical/optical elements may include lenses, mirrors, diffraction gratings, windows, filters, waveguides, fibers, or any physical/optical element for directing and/or shaping (e.g., beam shaping) EM radiation from a radiation source to be incident on the alkali atoms within vapor cell 102.

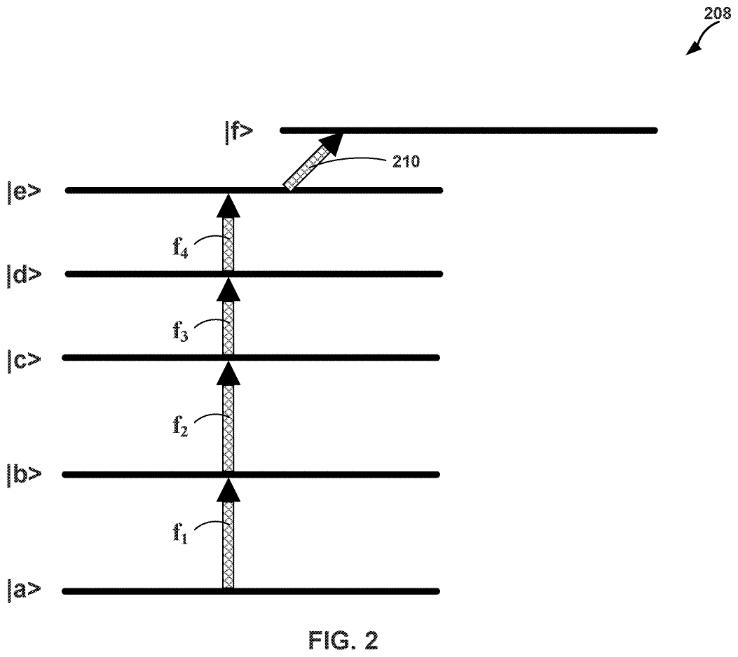

In some examples, preparation system 108 may include a plurality of EM radiation frequencies arranged to be incident on alkali atoms within vapor cell 102. In the example shown, preparation system 108 includes three EM radiation “beams” each including at least one EM radiation frequency different from each other and directed into vapor cell 102 and may be referred to as a “three-photon” preparation system 108. In some examples, preparation system 108 may include more or fewer than three EM radiation frequencies, e.g., two EM radiation frequencies or four or more EM radiation frequencies. In some examples, the plurality of EM radiation frequencies of preparation system 108 may be configured to prepare alkali atoms within vapor cell 102 to be in a Rydberg state via one or more intermediate quantum energy states, e.g., as further illustrated and described below with respect to FIG. 2. In some examples, preparation system 108 may be configured to prepare the alkali atoms within vapor cell 102 to be in a Rydberg state with an orbital angular momentum quantum number 1, that is at least the number of quanta/frequencies of the plurality of EM frequencies, e.g., 1≥3 in the example shown. In some examples, preparation system 108 may be configured to prepare the alkali atoms within vapor cell 102 with a principal quantum number n that is less than or equal to 200, e.g., n≤200.

FIG. 2 is an illustration of an example energy diagram 208 of an alkali atom including at least one Rydberg state, in accordance with the techniques of the disclosure. In some examples, energy diagram 208 may correspond to an example preparation system for preparing alkali atoms to be in a Rydberg state, such as preparation system 108 of FIG. 1. In some example, the alkali atom prepared via energy diagram 208 in the Rydberg state, e.g., quantum energy state |e> in the example shown, may have a relatively low quantum number (n≤200) and a relatively high orbital angular momentum (1≥3). For example, a sensor may be configured to prepare alkali atoms in a Rydberg state with an orbital angular momentum corresponding to an orbital angular momentum quantum number that is at least at least 3 (1≥3).

Energy diagram 208 illustrates a “four-photon” excitation system or preparation system. In the example shown, atoms may be excited from a ground state |a> to a Rydberg state |e> via multiple transitions between multiple quantum states and/or energy states |b>, |c>, and |d>. In the examples shown, incident EM radiation 210 may excite and/or perturb the atoms in the Rydberg state |e> to another state |f>, which may be detectable via the methods described herein, e.g., via probe beam (EIT). The atoms may be excited to each subsequent level, e.g., |b> through |e>, via incident EM radiation of a specific frequency, e.g., frequencies f₁, f₂, f₃, f₄ (each of which may also be referred to as a “photon” of the “four-photon” system in reference to the energy of each photon being directly proportional to its frequency f₁, f₂, f₃, or f₄, although it is to be understood that multiple atoms may be excited from one energy state to another energy state via multiple photons of the same energy). In some examples, exciting the atoms from a lower quantum/energy state, e.g., ground state |a>, to Rydberg state |e> via multiple transitions, e.g., three or more, may result in atoms in the Rydberg state with a lower quantum number n and a higher orbital angular momentum quantum number 1 in relation to exciting the atoms via a single and/or two-photon transition. Although energy diagram 208 illustrates a four-photon system, in some examples the methods and techniques disclosed herein may utilize a different number of quantum energy levels, e.g., a two-photon system (e.g., two EM radiation frequencies), a three-photon system (e.g., three EM radiation frequencies), or more than four photons (e.g., more than four EM radiation frequencies). For example, one or both of EM radiation frequencies f₃, f₄ may be optional, intermediate states |c>, and |d> may be optional, and EM radiation frequencies f₁, f₂ may be configured to excite alkali atoms to the desired Rydberg state, e.g., from ground state |a> to Rydberg state |e>.

In one example, energy diagram 208 may be an “all-optical” excitation system (e.g., preparation system 108) in which the EM radiation for each of f₁, f₂, f₃, f₄ are all in the ultra violet (UV), visible, or infrared (IR) frequency and/or wavelength ranges. At least one electron of a rubidium atom may be excited from the ground state |a>, which may be a |5S_{1/2}> energy state, to a second energy state (e.g., alternatively referred to as a first intermediate state), |b>, which may be a |5P_{3/2}> energy state, via 780 nanometer (nm) EM radiation (e.g., visible and/or near infrared (NIR) light) having a frequency f₁ of about 384.349 THz. Hereinafter, excitation of at least one electron of an atom may alternatively be stated as “the atom may be excited,” e.g., to a particular energy state, although it is understood that it is one or more electrons of one or more atoms which may be excited to a different energy state. The rubidium atom may further be excited from the second energy state |b> to a third energy state |c>, which may be a |4D_{5/2}> energy state via 1.52937 NIR light, e.g., corresponding to EM radiation having a frequency f₂ of about 196.023 THz. The rubidium atom may further be excited from the third energy state |c> to a fourth energy state |d>, which may be a |4F_{7/2}> energy state via 1.34464 NIR light, e.g., corresponding to EM radiation having a frequency f₃ of about 222.954 THz. The rubidium atom may further be excited from the fourth energy state |d> to a fifth, e.g., Rydberg energy state |e>, which may be any one of a plurality of |nG> Rydberg energy states via a tunable NIR/IR light, e.g., EM radiation having a tunable frequency f₄. In some examples, alkali atoms excited to the fifth Rydberg energy state |e> comprising one of an |nG> Rydberg energy state may have an orbital angular momentum number 1≥4. In some examples, alkali atoms excited to the fifth Rydberg energy state |e> comprising one of an |nG> Rydberg energy state may only have an orbital angular momentum number 1=4. In some example, n may be an integer ranging from 4 to 200, e.g., 4≤n≤200. In some examples, incident EM radiation 210 may be resonant with, e.g., able to further excite the rubidium atom to, at least one of a plurality of energy states |f>, which may be any of |(n+i)H> or |(n+i)F> Rydberg energy states, where i may be zero or any integer such that 4≤n+i for a F state and 6≤n+i for a H state. For example, incident EM radiation 210 may excite the rubidium atom to an energy state with the same quantum number n, e.g., i=0, or a different quantum number, e.g., i+0, as the Rydberg energy state |e>.

In some examples, incident EM radiation 210 may comprise a plurality of frequencies which may excite one or more rubidium atoms to one or more |(n+i)H> or |(n+i)F> Rydberg energy states, and for which one or more detection may be configured to detect. In other words, energy diagram 208 may be a preparation system 108 enabling a sensor 100 to sense a plurality of incident EM radiation 210 frequencies and amounts, e.g., concurrently or over a predetermined period of time.

In some examples, tunable EM radiation f₄ may be tuned to a plurality of frequencies, e.g., via scanning over a period of time, such that one or more rubidium atoms may be excited to a plurality of Rydberg |nG> energy states, each of which may be resonance with one or more frequencies of incident EM radiation 210, e.g., allowing EM radiation 210 to further excite the one or more rubidium atoms to one or more |(n+i)H> or |(n+i)F> energy states. In other words, energy diagram 208 may be a preparation system 108 enabling a sensor 100 to scan a tunable preparation EM radiation frequency, e.g., f₄, and thereby scan and sense a plurality of incident EM radiation 210 frequencies and amounts, e.g., to sense at least a portion of the spectral content of EM radiation 210 via the one or more detection systems further described below.

In some examples, tunable EM radiation f₄ may be about 205.337 THz, e.g., about 1460 nm IR light, and may be tunable across about +10 nm, e.g., from about 1450 nm to about 1470 nm or 203.94 THz<f₄<206.753 THz. Table 1 includes a plurality of example tunable EM radiation f₄ frequencies and corresponding |e> Rydberg energy states, each of which may be configured to sense incident EM radiation 210 including an on-resonant frequency with the corresponding |(n+i)H> energy state (the frequencies shown may be approximate). In other examples, energy diagram 208 may include any other suitable |e> Rydberg energy state with a quantum number n less than or equal to 200 and orbital angular momentum quantum number greater than or equal to 3 and prepared via any other suitable f₄ frequencies and configured to sense other EM radiation 210 frequencies on-resonant with any other suitable |f> energy state (e.g., any other suitable |(n+i)H> or |(n+i)F> energy state) not necessarily shown in Table 1.

TABLE 1

| | | | | |
|---|---|---|---|---|
| f₄ | n | \|e> | 208 | \|f> |

| | | | | | | |
|---|---|---|---|---|---|---|
| 1.46411 | μm | 40 | \|40G_{9/2}> | 189 | MHz | \|40H_{9/2}> |
| 1.45884 | μm | 50 | \|50G_{9/2}> | 97 | MHz | \|50H_{9/2}> |
| 1.45599 | μm | 60 | \|60G_{9/2}> | 56 | MHz | \|60H_{9/2}> |
| 1.45427 | μm | 70 | \|70G_{9/2}> | 35 | MHz | \|70H_{9/2}> |
| 1.45316 | μm | 80 | \|80G_{9/2}> | 24 | MHz | \|80H_{9/2}> |

In some examples, an all-optical excitation system of the current example may use other intermediate energy levels. For example, the all-optical system may use a |5P_{1/2}> energy state as the second |b> energy state and still result in one of the same Rydberg |nG> energy states as the above all-optical examples but via one or more different four-photon combinations of visible/NIR/IR EM radiation frequencies f₁, f₂, f₃, f₄.

In some examples, energy diagram 208 may be an excitation/preparation system using other alkali atoms besides and/or in addition to rubidium. For example, vapor cell 102 may comprise a vapor of cesium atoms, and preparation system 108 may comprise any of the example energy diagrams 208 described herein.

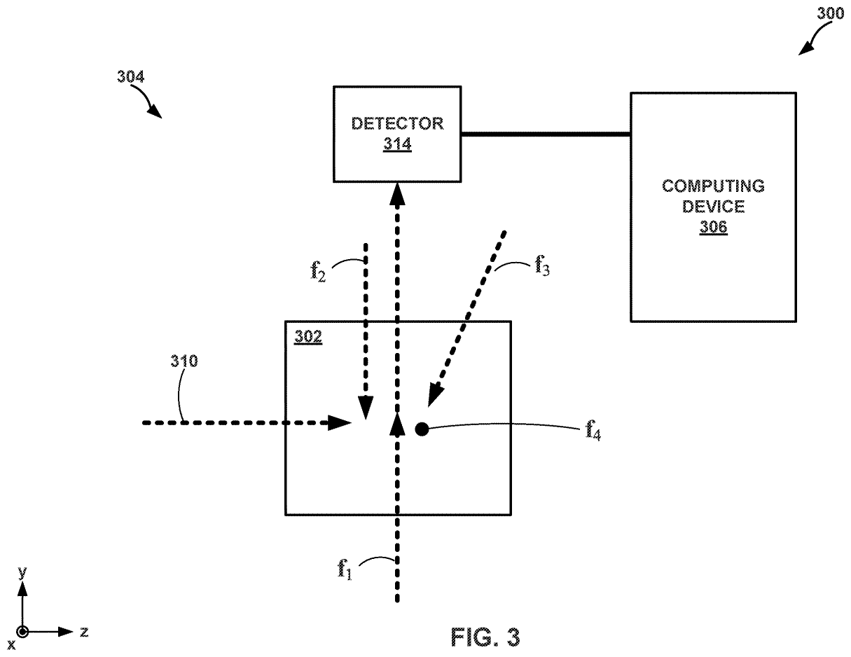

FIG. 3 illustrates an example detection system which may comprise and/or be used in conjunction with an EM radiation sensing system, e.g., example detection systems 104 of sensing system 100 of FIG. 1. FIG. 3 is a cross-sectional block diagram illustrating an example EM radiation sensing system 300 including a probe beam f₁ detection system 304 in accordance with the techniques of the disclosure.

In the example shown in FIG. 3, sensing system 300 includes vapor cell 302 which may correspond to vapor cell 102 of FIG. 1, detection system 304, computing device 306 which may correspond to computing device 106 of FIG. 1, a preparation system including EM radiations f₁ and f₂. In the example shown, sensing system 300 may be configured to sense and/or record incident EM radiation 310. In some examples, the preparation system may further include additional preparation EM radiations, e.g., f₃ and/or f₄, which may be configured to be directed into vapor cell 302 in the x-direction. Although illustrated as including four preparation EM radiations, the preparation system of sensing system 300 may include more or fewer preparation EM radiations, e.g., two preparation EM radiations (such as f₁, f₂ including a probe EM radiation and first and second coupling EM radiations), three preparation EM radiations (such as f₁, f₂, f₃ including a probe EM radiation and first and second coupling EM radiations) or five or more EM radiations.

In the example shown, detection system 304 operates in conjunction with the preparation system and includes detector 314, EM radiations f₁, f₂, f₃ and f₄ (f₄ is illustrated as propagating in the x-y plane), and any associated optical or RF components configured to direct EM radiations f₁, f₂, f₃, f₄ from their corresponding EM radiation sources and to be incident on one or more alkali atoms within vapor cell 302. In the example shown, EM radiation f₁ may be referred to as probe beam f₁ and is configured to be directed to detector 314 through vapor cell 302. Correspondingly, detector 314 is configured and positioned so as to sense/detect/capture probe beam f₁. For example, detector 314 may be a visible, NIR, and/or IR detector configured to sense visible, NIR, and/or IR light and probe beam f₁ may be visible, NIR, and/or IR light. In some examples, probe beam f₁ may be 780 nm EM radiation, e.g., f₁ of FIG. 2.

Detection system 304 may be configured to detect and/or determine current energy state of the alkali atoms within vapor cell 302 based on the transmission of probe beam f₁. For example, alkali atoms within vapor cell 302 prepared via the preparation system may exhibit electromagnetic induced transparency (EIT). In the presence of a strong on-resonant coupling EM radiation, e.g., EM radiation of f₁, f₂, f₃, f₄ having frequencies closely matched to the energy gap between respective quantum energy states, e.g., |b>, |c>, |d>, and |e> of FIG. 2, the index of refraction of the vapor of alkali atoms of vapor cell 304 may be modified for EM radiation frequencies near the frequency of probe beam f₁ and resulting in an EIT “window” of increased transmission in the transmission spectrum of the alkali atoms near that frequency, e.g., f₁. Detuning (e.g., from the strong on-resonance frequency) of at least one of the preparation EM radiations f₁, f₂, f₃, and/or f₄ may change the index of refraction of the alkali atoms and consequently the transmission of probe beam f₁. A plot of the transmission as a function of detuning of at least one of f₁, f₂, f₃, and/or f₄ may include features characteristic and/or indicative of the energy state of the alkali atoms prepared to be in that state via the preparation system. Incident EM radiation 310, which may correspond to incident EM radiation 110 and/or 210 of FIGS. 1 and 2 respectively, may perturb the energy state of the alkali atoms (e.g., the energy state of at least one electron of the alkali atoms), for example, to a different energy state. A plot of the transmission as a function of detuning may be characteristic of the different energy state, and the amount and/or spectral content of the incident EM radiation 310 may then be inferred via one or more features of the transmission as a function of detuning, e.g., as sensed/detected/measured via detector 314.

To sense/detect a response of alkali atoms prepared in a Rydberg state to incident EM radiation 310 having lower frequencies, the alkali atoms may be prepared in higher orbital-angular momentum Rydberg states (e.g., F, G electron shells) via a preparation system or “path” including relatively lower quantum number energy states (and corresponding smaller electron shell diameters) that are not as easily further perturbed by external fields and atom-particle interactions. For example, the all-optical preparation system of FIG. 2 may allow sensing systems 100, 300 to sense/detect EM radiation 110, 310 having lower frequencies.

In other words, incident EM radiation 310 may perturb the EIT of the alkali atoms in vapor cell 302, and detection system 304 may comprise an optical probe beam and optical detector configured to detect/capture one or more features of the EIT of the alkali atoms, e.g., in conjunction with a three-photon, four-photon, or more than four-photon alkali atom preparation system. System 300 may determine an amount and/or spectral content of the incident EM radiation 310 based on the one or more features of the EIT of the alkali atoms, and may be configured to determine EM radiation 310 comprising relatively lower EM frequencies, e.g., in the MHz-THz frequency ranges. In some examples, probe beam f₁ may be at any angle relative to a surface of vapor cell 302 suitable for measurement.

Detector 314 may be configured to detect electromagnetic radiation, for example, infrared and/or visible light. Detector 314 may be large-bandgap solid-state visible wavelength detectors configured to operate at without cooling, e.g., at room temperature. For example, detector 314 may be a charge-coupled device (CCD), a metal-oxide-semiconductor based detector such as a complementary metal-oxide-semiconductor (CMOS) array or N-type metal-oxide-semiconductor (NMOS) detector, a PIN photodetector or a balanced photoreceiver. Detector 314 may be configured to detect probe light f₁ and may be configured to output one or more signals proportional to the detected probe light f₁. For example, detector 314 may be configured to output analog and/or digital signals representing a transmission of probe light f₁ as a function of detuning. Detector 314 may include any suitable imaging optics, such as, but not limited to, a lens, a 1D or 2D lens array, a mirror and/or mirror array with or without optical power, one or more diffraction gratings, one or more optical fibers, e.g., for injecting probe light f₁ into vapor cell 302 and/or collecting probe light f₁ after having transmitted through vapor cell 302, stackable focusing optics, and the like. In some examples, imaging optics are configured to direct and/or focus probe light f₁ onto one or more optical detecting elements of detector 314.

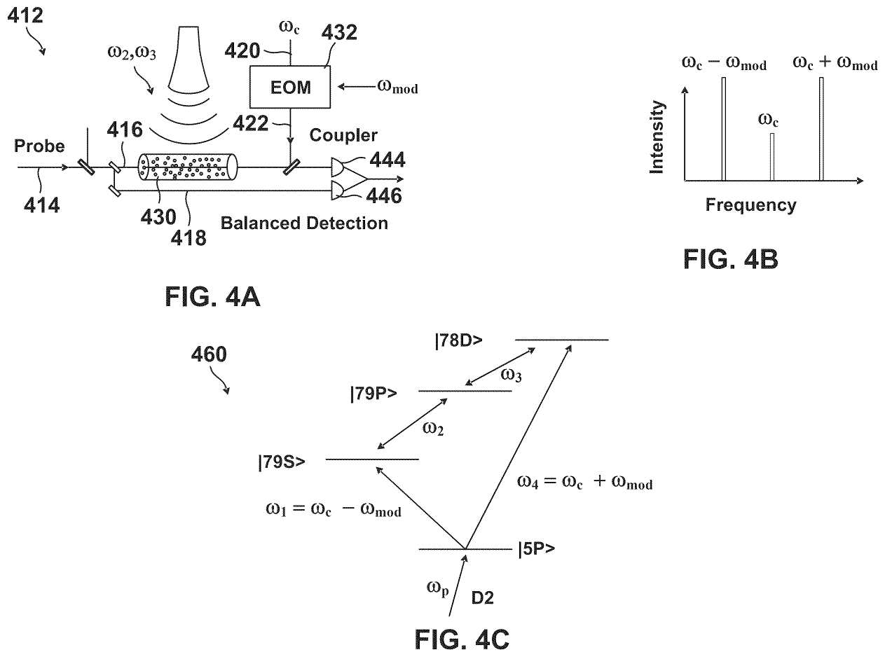

FIGS. 4A-4C illustrate another example EM radiation sensor 412 utilizing a quantum interference loop, in accordance with the techniques of the disclosure. EM radiation sensor 412 may be an example of sensor 112 of FIG. 1 or detection system 304 of FIG. 3, but with the differences described below. FIG. 4A is a diagram illustrating EM radiation sensing sensor 412 utilizing a balanced probe beam detection system, FIG. 4B is a plot 450 illustrating the frequency spectrum of coupling radiation used in the balanced probe beam detection system of the system of FIG. 4A, and FIG. 4C is an illustration of an EIT energy diagram 460 and quantum energy states illustrating a quantum interference loop corresponding to EM radiation sensor 412 of FIG. 4A, in accordance with the techniques of the disclosure. In some examples, the energy diagram 460 represents a phase-sensitive quantum interference loop.

In some examples, EM radiation sensor 412 may be an atomic receiver configured to detect an incident EM phase of incident electromagnetic (EM) radiation, e.g., an incident RF radiation, without the use of a local oscillator, e.g., without the use of an RF local oscillator. In some examples, a system, such as detection system 304 including EM radiation sensor 412, may be configured to determine a phase value of the detected incident EM phase without limiting the phase value to any range of phase values. For example, the system including EM radiation sensor 412 may be configured to determine the phase of the incident EM phase within the full 360-degree range of phases, e.g., as opposed to being limited to only half, or some other portion, of the full range of phase values. In some examples, EM radiation sensor 412 may include an electrically small receiver, e.g., a receiver that may be smaller than about a half-wavelength of incident EM radiation 310 (e.g., and/or incident RF radiations ω2, ω3). For example, vapor cell 430 may comprise a receiver, e.g., one or more alkali atoms, that may be smaller than about a half-wavelength of incident EM radiation 310.

In the example shown in FIG. 4A, EM radiation sensor 412 includes probe EM radiation 414 and coupling EM radiation 420. In some examples, one or both of probe EM radiation 414 and coupling EM radiation 420 may be laser radiation, e.g., coherent, or at least partially coherent, and substantially monochromatic, or at least substantially quasi-monochromatic EM radiation and/or light. In the example shown, probe EM radiation 414 is split via a splitter into signal probe EM radiation 416 and reference probe EM radiation 418. In the example shown, signal probe EM radiation 416 and coupling EM radiation 422 irradiate a plurality of alkali atoms within vapor cell 430 are counter-propagating within vapor cell 430 and are spatially overlapping within vapor cell 430. Vapor cell 430 comprises a plurality of alkali atoms, e.g., rubidium atoms in the example shown, and may be substantially similar to vapor cell 402 described above except for the differences described herein. Probe EM radiation 414 may have an angular frequency ω₁ (where ω=2πf₁, where f is frequency) which may be an optical frequency. Coupling EM radiation 420 may have an angular frequency ω_{c}, which may be an optical frequency. In the example shown, coupling EM radiation 420 is incident on electro-optical phase modulator (EOM) 432, which may output coupling EM radiation 422 comprising sidebands of coupling EM radiation 420. For example, EOM may be driven by an external phase-stabilized signal at a frequency ω mod to generate sidebands on coupling EM radiation 420 frequency ωc, and coupling EM radiation 422 may include a plurality of frequencies, e.g., ω_{c}, ω1=ω_{c}−ω_{mod} and ω4=ω_{c}+ω_{mod}, as shown in FIG. 4B. In the example shown, ω_{mod}=2π×4.352 GHz.

As shown in FIG. 4C, probe EM radiation 414 on the D2 transition first couples the ground state of the alkali atoms (e.g., rubidium atoms) to the 5P_{3/2} state. The two EOM generated sidebands at ω1=ω_{c}−ω_{mod} and ω4=ω_{c}+ω_{mod} then couple to the 79S_{1/2} and 78D_{5/2} states, respectively. In the example shown, these states are then linked through the 79P_{3/2} state via two RF-frequency transitions at EM radiation ω2=2π×7.292 GHz (SP transition) and EM radiation ω3=2π×4.352 GHz (DP transition). For example, the states may be linked, or an interferometric loop may be completed, by EM radiations ω2 and ω3, one of which may correspond to an incident EM radiation being detected (e.g., an RF field under test, of interest, or the like), and the other of which may be a control EM radiation, or a “control photon” that is part of the preparation system and/or interferometric loop that may be completed by the incident EM radiation. For example, the alkali atoms in vapor cell 430 may be excited to one or more of a plurality of states (FIG. 4C) with one of the transitions (e.g., one of ω2 and ω3 in the example shown) corresponding to an RF field being detected, completing the quantum mechanical interferometric loop and causing an interferometric response of the rubidium atoms and causing a response in the EIT of the rubidium atoms that is detectable via, for example, balanced detection of signal probe EM radiation 416 and reference probe EM radiation 418. In other examples, at least one of radiations ω2 or ω3 may be an optical frequency rather than an RF frequency, e.g., for an all-optical preparation system, the loop being completed by an RF field being detected. In some examples, at least one of radiations ω2 or ω3, e.g., the control EM radiation, may be phase-locked to at least one of radiations ω1 and/or ω4. For example, at least one of EM radiations ω2 or ω3 may correspond to the control EM radiation or “control photon” that is phase-locked with the “sideband photons” (e.g., radiations ω1, ω4) of the quantum interferometric loop, and the other may correspond to the incident EM radiation, e.g., the radiation under test. In still the other examples, ω1 and ω4 may couple to states that are linked through a single EM radiation, e.g., ω2 or ω3, which may be an incident RF frequency completing the interferometric loop.

In the example shown, the frequencies (ω) and phases (φ) of this loop state arrangement are related by ω1+ω2+ω3=ω4 and φ1+2+φ3=φ4. Using the two EOM 432 generated sidebands, these relationships reduce to ω2+ω3−2ω_{mod}=0 and φ2+φ3−2φ_{mod}=0. One notable benefit of this system is that any frequency or phase noise and/or drift in the EM coupling EM radiation 420 or 422 cancels out, with the only remaining dependence being on the phase-locked RF field ω2 and ω3 (where “field” may refer to an electric field having a particular frequency or EM radiation having a particular frequency). In the example shown, the set of states is chosen based on the narrow bandwidth of EOM 432 of about 5.8 GHz, but this approach is generally applicable, e.g., for other state manifolds.

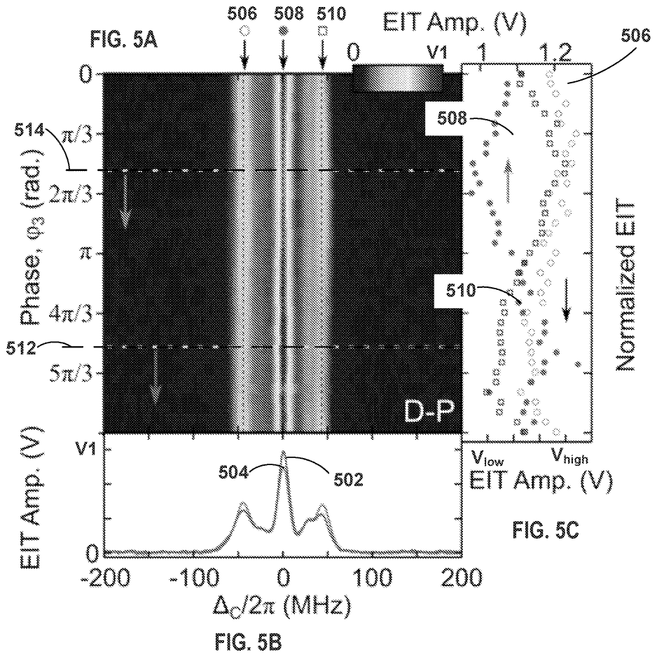

FIGS. 5A-5C illustrate the phase-sensitivity of the quantum interference loop illustrated by energy level diagram 460 of FIG. 4C. FIG. 5A is a heatmap, e.g., two-dimensional plot, illustrating the amplitude or intensity of signal probe EM radiation 416 of the EM radiation sensor 412 of FIG. 4A as a function of coupling EM radiation 420 detuning and control photon phase, e.g., the phase of at least one of coupling EM radiation 420, coupling radiation sideband ω1, coupling radiation sideband ω4, or EM radiation ω3. FIG. 5A may illustrate the amplitude of the EIT spectra of the plurality of alkali atoms of vapor cell 430 excited according to the EIT energy scheme/diagram of FIG. 4C as a function of the phase of ω3 of the DP transition (vertical axis) and as a function of detuning coupling EM radiation 420 (horizontal axis).

FIG. 5B is a plot illustrating the example signal probe EM radiation 416 of the EM radiation sensor 412 of FIG. 4A as a function of coupling EM radiation 420 detuning at the two phases indicated in FIG. 5A at lines 512, 514. FIG. 5B may illustrate a plot of two EIT spectra of the plurality of alkali atoms of vapor cell 430 excited according to the EIT energy scheme/diagram of FIG. 4C at two different phases of ω3 as a function of detuning coupling EM radiation 420, the two phases taken along the lines 512, 514.

FIG. 5C is a plot illustrating the example signal probe EM radiation 416 of the EM radiation sensor 412 of FIG. 4A as a function of control photon phase, e.g., the phase of at least one of coupling EM radiation 420, coupling radiation sideband ω1, coupling radiation sideband ω4, or EM radiation ω3, at the three coupling EM radiation 420 detuning frequencies indicated in FIG. 5A at lines 506, 508, 510. FIG. 5C illustrates a plot of the EIT amplitude at detuning frequencies corresponding to the three prominent peaks along the lines 506, 508, 510 as a function of phase (φ3) of ω3 of the DP transition. In the examples shown, the EIT spectra 502, 504 is the amplitude of the balanced detection of signal probe EM radiation 416 and reference probe EM radiation 418, e.g., at detectors 444, 446, as a function of detuning Δc of coupling EM radiation 420.

In the examples shown, the accumulated phase of the quantum interferometric loop 460 is due to all EM fields involved and the EIT measurement is sensitive to changes in phase of any of the fields. FIG. 5A illustrates the superposition EIT signal as φ3 is swept over 360 degrees. FIG. 5C illustrates a clear oscillation in the EIT amplitude with a period of 360 degrees and with the central EIT peak and the AT-doublets (side peaks) out of phase by 180 degrees.

The relative phases and frequencies of the three applied EM fields, e.g., ω1, ω4, and ω2 or ω3, fixes a reference frequency and phase on the fourth transition, e.g., ω3 or ω2. In some examples, frequency locked to the frequency of this reference may be used, which represents a homodyne measurement. The reference phase and frequency are not the result of an applied field, but rather are encoded in the quantum mechanical wave functions of the Rydberg states adjacent to the transition being measured, e.g., either the SP transition or the DP transition. In some examples, the reference may be used in a heterodyne configuration.

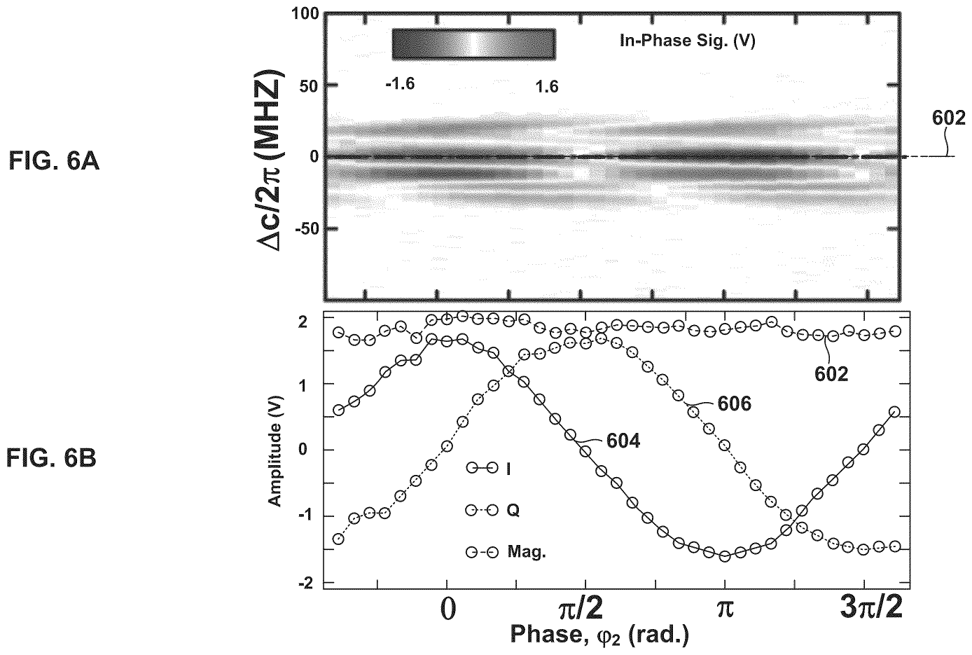

For example, one of the EM radiations, e.g., ω3, may be a “control photon” may be applied at a detuned frequency ω3′=ω3+8. This detuned frequency may be equivalent to a resonant frequency with a time-varying phase, e.g., ω3+8=ω3+dφ/dt, and the resulting oscillation in the EIT signal may be demodulated using lock-in detection at frequency δ, where the lock-in phase provides a direct measure of the EM radiation phase φ2 of ω2. In some examples, detuning and demodulations of EM radiation ω3 may be used to measure either φ2 or φ3. FIG. 6A is a plot of the φ2-dependent in-phase (I) lock-in mixer signal as a function of coupling EM radiation 420 detuning (Δ_{C}). The example shown in FIG. 6A illustrates a 360-degree phase sensitivity. FIG. 6B is a plot of the corresponding φ2 dependent evolution of the in-phase 604 and out-of-phase 606 (e.g., quadrature Q) signals taken along the line 602 in FIG. 6A. As shown in FIG. 6B, the I and Q components of the RF signal may be demodulated simultaneously. Plot 608 is the lock-in magnitude.

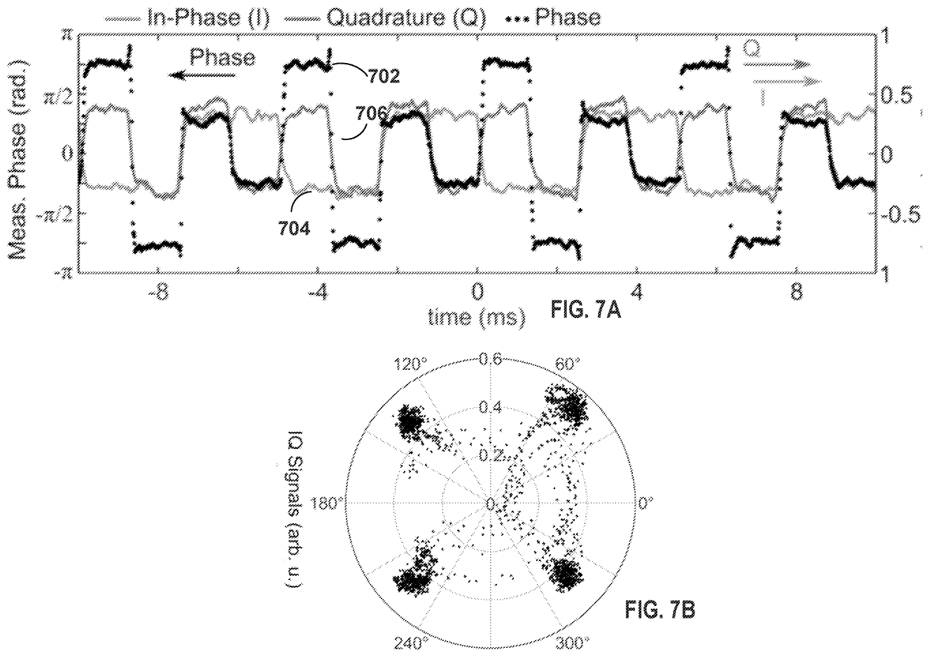

In some examples, a quantum interference loop, e.g., quantum interferometric loop 460, may be used as a Rydberg mixer for quadrature phase shift keying (QPSK). For example, a four phase-state φ3 signal generated using an IQ mixer may be applied to simulate a QPSK signal. FIG. 7A is plot of a lock-in output of a simulated QPSK signal with a symbol rate of 800 Hz. In the example shown, plot 702 illustrates well-resolved phase states together with the corresponding orthogonal I channel 704 and Q channel 706. FIG. 7B is a polar plot constellation diagram of the phases 702 of FIG. 7A, illustrating the four well-resolved phase states detected.

The use of the phase-coherent quantum interferometric loop of FIG. 4C may provide notable advantages compared to conventional Rydberg mixer approaches. For example, due to the dependence of the signal on the accumulated phase over the interferometric loop, one field (e.g., ω2 or ω3) may be detuned to generate a mixer that measures the phase of a different field. With the necessary presence of at least four fields to complete the loop, this may enable new modulation and frequency mixing systems for detection of demodulation of RF fields.

For example, the use of degenerate RF frequencies may be a special case of the approach shown in the example of FIG. 4C. Using two degenerate transitions, e.g., ω2=ω3, the RF phase is accumulated on both transitions φtot=φ2+φ3=2φRF, where the doubled phase provides only 180° phase resolution and thus renders common phase modulation systems unusable. However, with the approach shown in FIGS. 4A-4C, the ability to apply a field on one transition in order to measure another allows frequency separation of the two fields, potentially into distinct bands, and improving sensitivity by requiring one RF photon in the signal rather than two, providing a full 360 degree of phase resolution. In some examples, an all-optical approach of FIGS. 4A-4C (e.g., where either of ω2 or ω3 is an optical frequency) may provide the ability to apply a field on an optical transition in order to measure an RF, or another optical, transition. An all-optical system may be useful for sensing applications where broadcasting an LO field (e.g., an RF LO oscillator) in the spectral vicinity of the signal of interest is undesirable.

In some examples, although FIG. 4C illustrates a four-photon system involving a preparation system including three optical fields and one RF field, and the RF field under test or being detected, an all-optical system may include a three-photon system involving three optical fields (e.g., preparation fields including a probe optical field and first and second coupling optical fields) and one RF field (e.g., the RF field under test or being detected) for which a phase is determined via I/Q demodulation (without using an RF local oscillator).

In other examples, different manifolds may be used than shown in FIG. 4C. For example, two or more EM radiations (e.g., laser beams) may be directed through vapor cell 430, e.g., probe EM radiation 416 coupling the ground state to the 5P_{3/2} state, coupling EM radiation 420 (e.g., without sidebands) coupling the 5P_{3/2} state one of the 79S_{1/2} or 78D_{5/2} states, and a relatively higher energy UV laser radiation (not shown) coupling the ground state to the other one of the 79S_{1/2} and 78D_{5/2} states. In some examples, other states may be used, but with the RF radiation under test, e.g., similar to ω2 or ω3 of FIG. 4C, completing the loop. In other examples, a three-photon system involving two optical fields may be used. For example, coupling EM radiation 420 may provide a transition to couple between the 5P_{3/2} state and the 78D_{5/2} state, and UV laser radiation may couple the ground state directly to the 5P_{3/2} the 79S_{1/2}, with RF radiation ω3 under test completing the quantum interferometric loop.

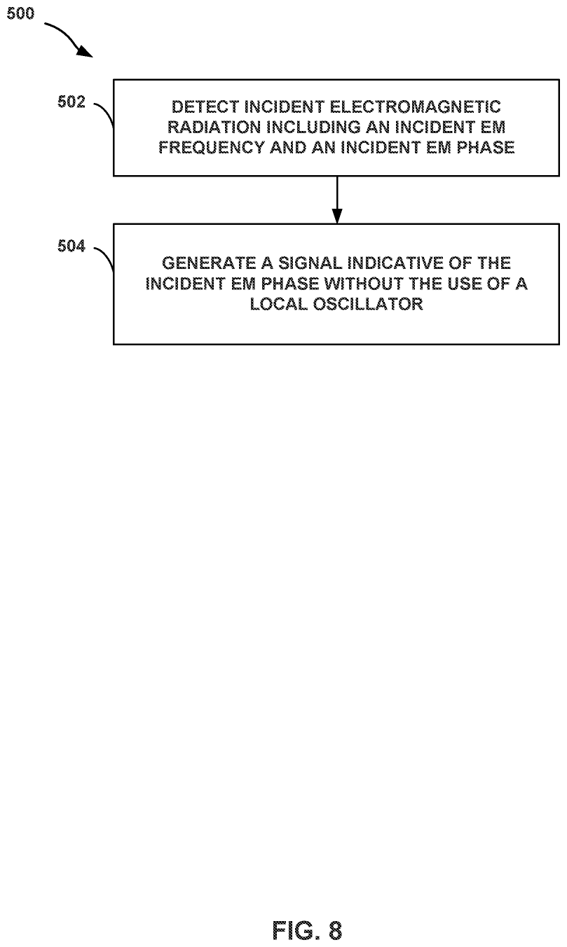

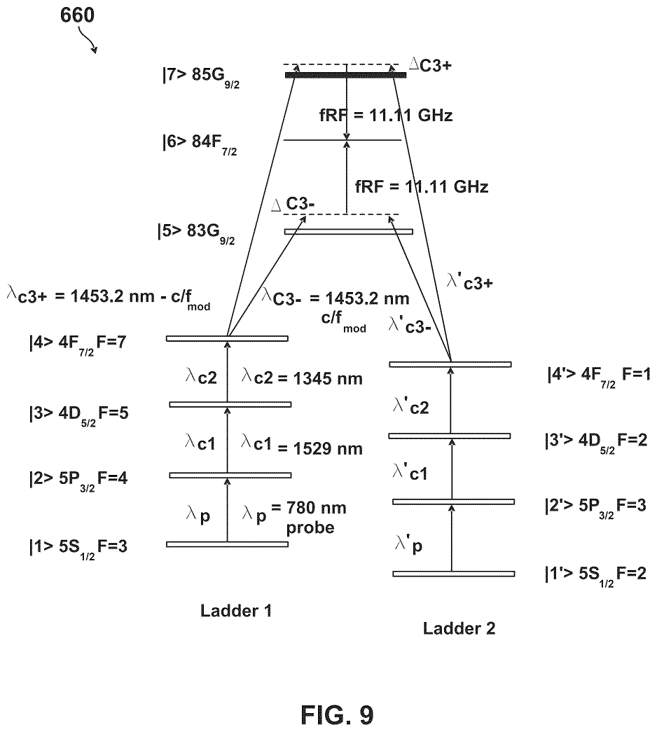

FIG. 8 is a flowchart of an example method 500 of sensing incident EM radiation, in accordance with the techniques of the disclosure. The method 500 is described with reference to sensor 112 of sensing system 100 of FIG. 1, detection system 304 of FIG. 3, EM radiation sensor 412 and EIT energy diagram 460 of FIGS. 4A-4C, the dual energy diagram of FIG. 9, and with reference to any of FIGS. 1-3.

EM radiation sensor 412, which may be an atomic receiver, may detect incident EM radiation including an incident EM frequency (e.g., ω2 or ω3) and an incident EM phase (e.g., φ1 or φ2) (502). For example, EM radiation sensor 412 may detect and/or receive incident EM radiation 110 (FIG. 1), EM radiation 210 (FIG. 2), incident EM radiation 310 (FIG. 3), or incident EM radiations ω2 or ω3 (FIGS. 4A-4C).

In some examples, EM radiation sensor 412 may excite a plurality of alkali atoms in a vapor cell 430, via EM radiation, from a first quantum state to a plurality of Rydberg states comprising a quantum interferometric loop, e.g., as shown in FIG. 4C. In some examples, EM radiation sensor 412 may excite the plurality of alkali atoms in the vapor cell 430 to be in Rydberg states with an orbital angular momentum quantum number 1 that is at least the number of quanta of the one or more frequencies. In some examples, EM radiation sensor 412 may excite the plurality of alkali atoms in the vapor cell 430 to be in a Rydberg states with an orbital angular momentum quantum number that is at least 3 (1≥3). In some examples, EM radiation sensor 412 may excite the plurality of alkali atoms in the vapor cell 430 to be in a Rydberg states with a principal quantum number of the alkali atoms in the second quantum state is less than or equal to 200 (n≤200).

For example, EM radiation sensor 412 may excite the plurality of alkali atoms via a four-photon preparation system 460 as illustrated and described above with reference to FIGS. 4A-4C. In some examples, EM radiation sensor 412 may be a part of a sensing system 100, and computing device 106 may cause preparation system 108 to excite the plurality of alkali atoms in vapor cell 430 to be in a Rydberg energy state with n≤200 and 1≥3.

In some examples, EM radiation sensor 412 may excite the plurality of alkali atoms in vapor cell 430 via EM radiation including a probe EM radiation, a first coupling EM radiation having a first coupling frequency and a first coupling phase, a second coupling EM radiation having a second coupling frequency and a second coupling phase, and a control EM radiation having a control frequency and a control phase. For example, EM radiation sensor 412 may excite the plurality of alkali atoms in vapor cell 430 via probe EM radiation 416 and coupling EM radiation 422 including a first coupling EM radiation ω1 and a second coupling EM radiation ω2, and a control EM radiation ω3 or ω4 (the other of which may be the incident EM radiation under test in the example shown in FIG. 4C).

In some examples, two or more of the first coupling phase (φ1), the second coupling phase (φ2), and the control phase φ3 or φ4 (the other of which may be the incident EM phase under test in the example shown in FIG. 4C) are phase-locked relative to each other and/or correspond to each other with a known and/or predetermined correspondence. In some examples, the probe frequency, the first coupling frequency (ω1), and the second coupling frequency (ω2), and the control frequency (ω3 or ω4) comprises at least one of an ultraviolet (UV), a visible, or a near-infrared (NIR) frequency, and in some examples the incident EM radiation (e.g., ω4 or ω3) may comprise an RF. For example, EM radiation sensor 412 may be configured to excite the plurality of alkali atoms in vapor cell 430 via EM radiation of one or more optical frequencies, e.g., in an “all-optical” excitation scheme and/or interferometric loop configured to detect incident RF radiation. In some examples, the optical frequencies may include UV, visible, and IR frequencies, and may range from extreme ultraviolet (EUV), e.g., less than about 30,000 THz, to long-wave infrared (LWIR), e.g., greater than about 20 THz.

The sensor 412 may detect, via the probe EM radiation, an interferometric response of the plurality of alkali atoms upon excitation of the alkali atoms by the incident EM radiation). The interferometric response may be indicative of the incident EM phase. For example, EM radiation sensor 412 may include a detection system 104 configured to detect a response of the alkali atoms in the Rydberg state to incident EM radiation 110. In some examples, detection system 104 may include detecting a change in electromagnetic induced transparency (EIT) of the alkali atoms for the EM radiation of the first frequency, e.g., such as illustrated and described above with reference to FIGS. 3 and/or FIGS. 4A-4C.

In some examples, the incident EM frequency of the incident EM radiation comprises a radio frequency, e.g., having a frequency between 10 megahertz and 1 terahertz.

The EM radiation sensor 412 may generate a signal indicative of the incident EM phase based on the detected incident EM radiation and without the use of a local oscillator (504). For example, EM radiation sensor 412 may generate the signal based on the interferometric response. In some examples, EM radiation sensor 412 may output the signal, e.g., to an interface component or output device, such as a display. In some examples, EM radiation sensor 412 may output one or more values corresponding to the presence, amount (e.g., strength or amplitude), and/or spectral content of the incident EM radiation.

In some examples, the EM radiation sensor 412 may generate an in-phase signal and a quadrature signal (I/Q) based on the interferometric response. For example, EM radiation sensor 412 may output the signal proportional to the detected interferometric response as an I/Q signal or signals to computing device 106, which may comprise processing circuitry configured to determine the incident EM phase via demodulating the I/Q signal or signals. In some examples, the processing circuitry may determine a phase value of the incident EM phase within the full phase range of greater than or equal to 0 degrees and less than 360 degrees, without being limited to a particular range of phase values.

FIG. 9 is an illustration of an example dual energy diagram of an alkali atom of an example dual probe system for simultaneous I/Q phase readout, in accordance with the techniques of the disclosure. FIG. 9 is similar to FIG. 2 described above, except that FIG. 9 includes a dual-ladder preparation system for preparing alkali atoms to be in Rydberg states that are approximately equally energetically spaced, e.g., equally spaced such that the atoms may reach an nH state or nF state from a (n+1)G or an (n−1)G state via stimulated emission or absorption of a photon. Monitoring the probe beam(s) of such an all-optical, dual ladder preparation system enables phase sensitivity to an incoming RF field, e.g., to receive and/or detect phase-shift-keyed signals such as phase-shift-keyed GPS signals.

In some examples, an all-optical, dual-ladder preparation system may depend only on the easily controllable optical phase of coupling EM radiation sidebands and the unknown phase of the RF field. Preparing atoms with such a preparation system having high angular-momentum may be compatible with and/or may enable optical-based phase detection because the quantum defects of the F, G, and H states are nearly zero, such that energy states (n+1)G or an (n−1)G are approximately equally spaced from the nH state or nF state. Such symmetry may provide access to these states with symmetric optical sidebands (e.g., one of the two ladder systems shown in FIG. 6). In some examples, a small, applied DC Stark field (e.g., less than or equal to about 0.1 V/cm) may allow for an admixture of states such that Stark-mixed states can then be accessed by a single-photon optical transition out of the 4F7/2 state, as well, allowing for a similar symmetry within the same n-manifold, and thus, resonant, optically controlled, phase-sensitive access to very low (e.g., about 10 MHz) frequencies at low n. In the general system, two excitation pathways are achieved with modulation sidebands of the coupling EM radiation and absorption or stimulated emission of the RF photons. These two pathways combine coherently to produce an interference pattern on the EIT peak transmittance that is a function of the effective coupling Rabi rate cos²(φ_{RF}−φ_{ofs}), where φ_{RF} is the RF field phase and φ_{ofs} is the offset phase of the optical sidebands.

An all-optical phase detection system provides benefits relative to a heterodyne approach. For example, the all-optical technique provides a low profile and high RF field tolerance. The all-optical approach provides the LO directly to the spatial region of photon-atom overlap, without RF emissions, and does not require any bulk metal electrodes in the vicinity of the sensing vapor cell. Reducing the additional elements required for the sensor head will allow for maximum RF transparency. The all-optical system also provides simplified component integration via only optical fiber connections and a reduced sensing element size.

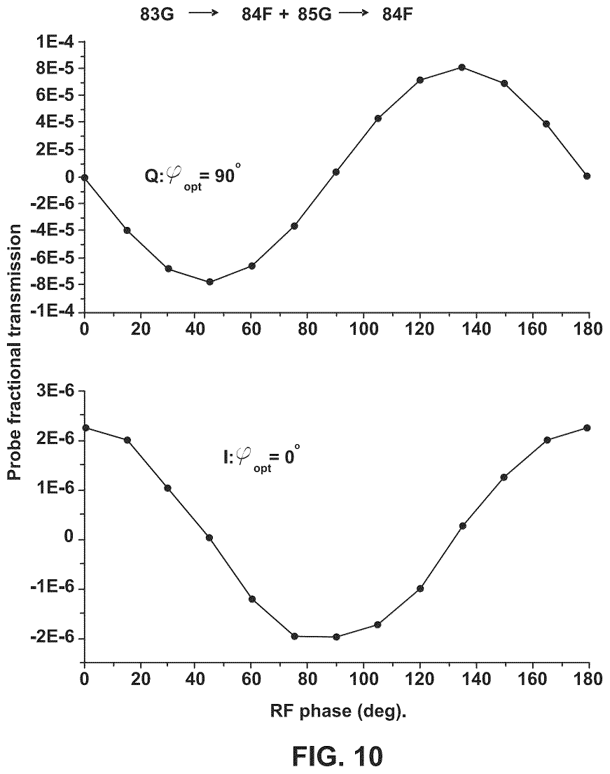

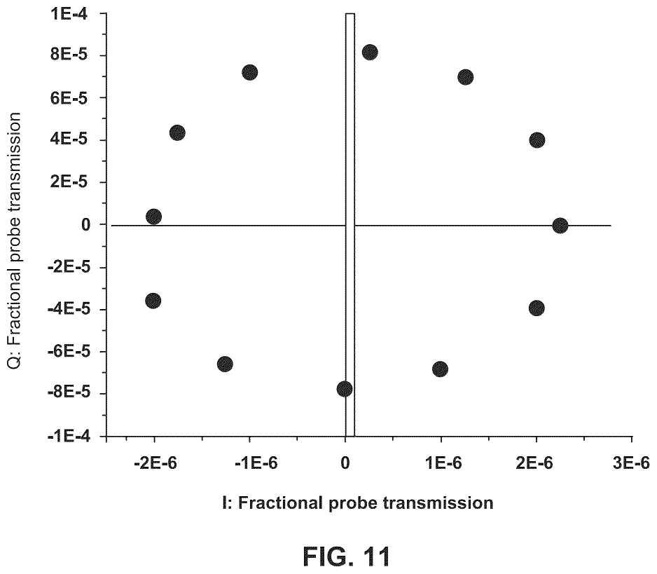

FIG. 10 is a pair of plots of an example demodulated I/Q signals corresponding to the fractional transmission of the dual probe beams of the dual probe system of FIG. 9, in accordance with the techniques of the disclosure, and FIG. 11 is a plot of an I/Q diagram of the demodulated I/Q signals of FIG. 10, in accordance with the techniques of the disclosure. In the examples shown, FIGS. 10 and 11 correspond to simultaneous I-Q readout for an all-optical, dual-probe (e.g., dual-ladder) preparation system of FIG. 9.

In some examples, the all-optical phase detection method provides a direct route for arbitrary signal demodulation. For example, by providing two coupling paths for EIT, the probe spectrum depends on the phase difference between the optical coupling field and the RF field. When the two coupling paths are both on resonance, and the RF field is detuned from resonance, the resulting AT peaks are 90 degrees out of phase. At a given optical phase, the AT peaks are representative of homodyne down-conversion at 0 degrees and 90 degrees. Monitoring the strength of each AT peak at a fixed optical phase may be equivalent to reading out the I and Q baseband modulation of the RF signal. The atoms in this configuration may act as a direct-conversion receiver, with the I and Q output in the probe transmission at the two coupler frequencies for the AT peaks.

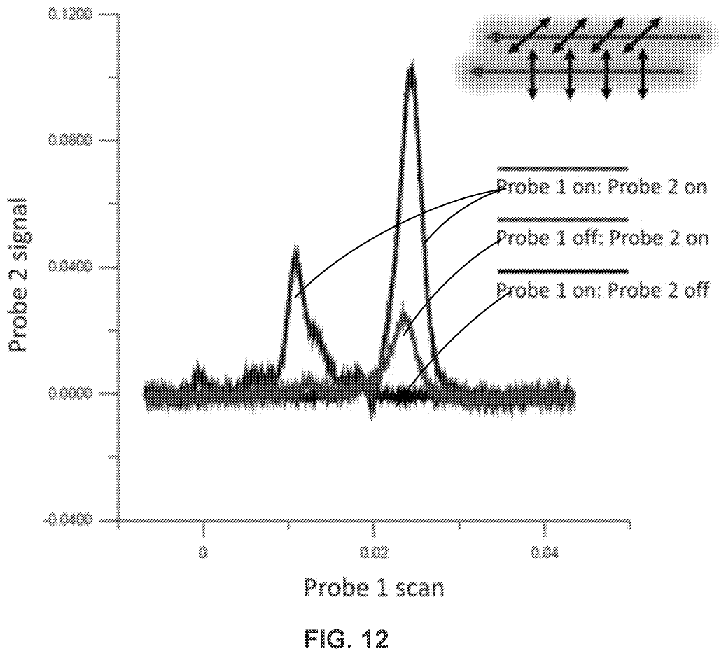

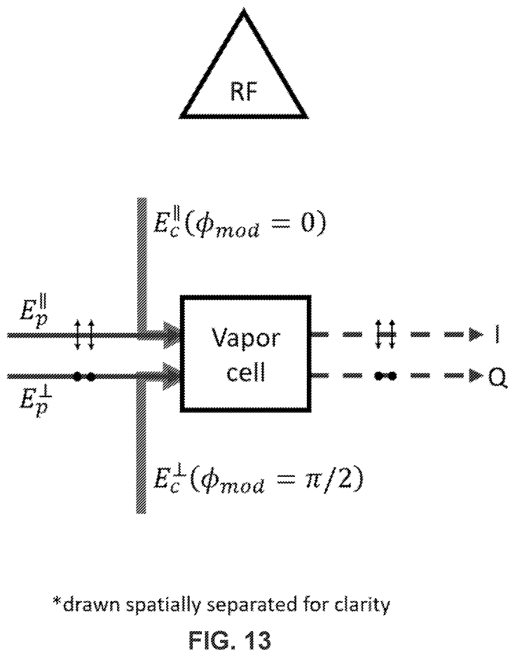

To distinguish AT peaks with a single probe beam, the coupling frequency may be modulated at a rate low enough for the atoms to respond, which may limit the RF modulation frequency. Also, the AT splitting may be large enough to be resolved, which may limit the sensitivity. In some examples, a second probe beam may be used, resonant with the hyperfine F=2−3 transition to distinguish AT peaks with a single probe beam. Additionally, a second set of coupling beams generated by frequency shifting the first set by the difference between the hyperfine levels of tens to hundreds, e.g., illustrated as Ladder 2 of FIG. 9. In some examples, coupling Rabi rates may be low enough, and amplified laser powers high enough, to frequency shift the first set by the difference between the hyperfine levels. In some examples, all beams may be overlapped in the vapor cell, using opposite polarizations for the probe beams, e.g., to be spatially split (e.g., via a polarizing beam splitter) and detected independently, as illustrated in FIGS. 12 and 13. FIG. 13 is a plot of an example probe signal of a dual probe system for simultaneous I/Q phase readout, in accordance with the techniques of the disclosure. FIG. 13 is a plot of example diagram of simultaneous I/Q phase readout, with I and Q being measured by orthogonally-polarized preparation and readout beams.

In some examples, a different coupling configuration may be used along with the orthogonally polarized fast-readout dual-probe system, e.g., to address the second challenge above. For example, when the two coupling fields are detuned from their resonances such that the two-photon detuning for each coupler-RF is zero, there may no longer be AT splitting, but rather a single EIT peak with an amplitude that is a function of the relative phase between the optical field and RF field. Instead of resolving the probe transmission at two coupling frequencies with the same optical phase, the I and Q channels will be read out at two different optical phases (e.g., as illustrated in FIGS. 10 and 11). The dual-probe system of FIGS. 9 and 13 may be used in the readout, and the two sets of coupling frequencies may be offset in phase by 90 degrees.

The following examples may illustrate one or more aspects of the disclosure:

Example 1: A method includes: detecting, by an atomic receiver, incident electromagnetic (EM) radiation comprising an incident EM frequency and an incident EM phase; and generating, by the atomic receiver and based on the detected incident EM radiation, a signal indicative of the incident EM phase, wherein the atomic receiver generates the signal without the use of a local oscillator.

Example 2: The method of example 1, wherein detecting the incident EM radiation comprises: exciting, via EM radiation, a plurality of alkali atoms from a first quantum state to a plurality of Rydberg states comprising a quantum interferometric loop, wherein the EM radiation comprises: a probe EM radiation having a probe frequency; a first coupling EM radiation having a first coupling frequency and a first coupling phase; and a second coupling EM radiation having a second coupling frequency and a second coupling phase, detecting, via the probe EM radiation, an interferometric response of the plurality of alkali atoms upon excitation of the alkali atoms by the incident EM radiation, wherein the interferometric response is indicative of the incident EM phase, wherein generating the signal comprises generating the signal based on the interferometric response; and outputting the signal.

Example 3: The method of example 2, wherein the first quantum state is a ground state, and wherein the incident EM frequency completes the interferometric loop.

Example 4: The method of example 2 or example 3, wherein the interferometric response is a first interferometric response, wherein the signal comprises a first signal, wherein the EM radiation further comprises a control EM radiation having a control frequency and a control phase, the method further including: changing the phase of at least one of the first coupling phase, the second coupling phase, or the control phase; detecting, via the probe EM radiation, a second interferometric response of the plurality of alkali atoms upon excitation of the alkali atoms by the incident EM radiation, wherein the second interferometric response is indicative of the incident EM phase; generating, by the atomic receiver and based on the second interferometric response, a second signal indicative of the incident EM phase, wherein the atomic receiver generates the second signal without the use of a local oscillator; and outputting the second signal.

Example 5: The method of example 4, wherein two or more of the first coupling phase, the second coupling phase, and the third coupling phase are phase-locked relative to each other.

Example 6: The method of any of example 4 or example 5, wherein each of the probe frequency, the first coupling frequency, the second coupling frequency, and the control frequency comprises at least one of an ultraviolet (UV), a visible, or a near-infrared (NIR) frequency, and wherein the incident EM frequency comprises a radio frequency.

Example 7: The method of example 6, wherein the radio frequency comprises a frequency between 10 megahertz and 1 terahertz.

Example 8: The method of any one of examples 2 through 7, wherein the signal based on the interferometric response comprises an in-phase signal and a quadrature signal.

Example 9: The method of any one of examples 2 through 8, the method further including: determining, based on the signal, the first coupling phase, and the second coupling phase, the incident EM phase, wherein determining the incident EM phase is not limited to any range of phase values.

Example 10: The method of example 9, wherein determining the incident EM phase comprises demodulating the in-phase signal and the quadrature signal without using a radio frequency local oscillator, wherein demodulating the in-phase signal and the quadrature signal is based on the signal, the first coupling phase and the second coupling phase.

Example 11: The method of any one of examples 2 through 10, wherein the interferometric response of the plurality of alkali atoms upon excitation of the alkali atoms by incident EM radiation comprises an electromagnetically induced transparency of the plurality of alkali atoms.

Example 12: The method of any one of examples 1 through 11, wherein the atomic receiver comprises an electrically small receiver.

Example 13: A sensing system including an atomic receiver configured to detect an incident EM phase of incident electromagnetic (EM) radiation without the use of a local oscillator.

Example 14: The sensing system of example 13, wherein the sensing system is configured to determine a phase value of the detected incident EM phase without limiting the phase value to any range of phase values.

Example 15: The sensing system of example 13 or example 14, wherein the atomic receiver comprises: a vapor cell including a plurality of alkali atoms; a preparation system configured to excite the plurality of alkali atoms from a first quantum state to a plurality of Rydberg states comprising a quantum interferometric loop, wherein the preparation system is configured to direct EM radiation of a plurality of frequencies into the vapor cell and incident on the vapor of alkali atoms, the preparation system comprising: a probe EM radiation having a probe frequency; a first coupling EM radiation having a first coupling frequency and a first coupling phase; and a second coupling EM radiation having a second coupling frequency and a second coupling phase; and a detector configured to detect an interferometric response of the plurality of alkali atoms upon excitation of the alkali atoms by the incident EM radiation comprising an incident EM frequency and the incident EM phase, wherein the detector is configured to output a signal proportional to the interferometric response of the plurality of alkali atoms, wherein the sensing system further comprises: processing circuitry configured to determine, based on the signal, the incident EM phase.

Example 16: The system of example 15, wherein the first quantum state is a ground state, and wherein the incident EM frequency completes the interferometric loop.

Example 17: The method of example 15 or example 16, wherein the interferometric response is a first interferometric response, wherein the signal comprises a first signal, wherein the preparation system further comprises a control EM radiation having a control frequency and a control phase, wherein the preparation system is further configured to change the phase of at least one of the first coupling phase, the second coupling phase, or the control phase, wherein the detector is further configured to: detect a second interferometric response of the plurality of alkali atoms upon excitation of the alkali atoms by the incident EM radiation, wherein the second interferometric response is indicative of the incident EM phase; and output, a second signal proportional to the second interferometric response of the plurality of alkali atoms, and wherein the processing circuitry configured to determine, based on the second signal, the incident EM phase.

Example 18: The system of example 17, wherein two or more of the first coupling phase, the second coupling phase, and the third coupling phase are phase-locked relative to each other.

Example 19: The system of example 17 or example 18, wherein each of the probe frequency, the first coupling frequency, the second coupling frequency, and the control frequency comprises at least one of an ultraviolet (UV), a visible, or a near-infrared (NIR) frequency, and wherein the incident EM frequency comprises a radio frequency.

Example 20: The system of example 19, wherein the radio frequency comprises a frequency between 10 megahertz and 1 terahertz.

Example 21: The system of any one of examples 15 through 20, wherein the signal proportional to the interferometric response of the plurality of alkali atoms comprises an in-phase signal and a quadrature signal, wherein to determine the incident EM phase the processing circuitry is further configured to: demodulate the in-phase signal and the quadrature signal without using a radio frequency local oscillator, wherein demodulating the in-phase signal and the quadrature signal is based on the signal, the first coupling phase, and the second coupling phase.

Example 22: A sensing system including: a vapor cell including a plurality of alkali atoms; a preparation system configured to direct optical electromagnetic (EM) radiation of a plurality of optical frequencies into the vapor cell and incident on the plurality of alkali atoms, the preparation system including: a probe electromagnetic (EM) radiation having a probe frequency; a first coupling EM radiation having a first coupling frequency and a first coupling phase; and a second coupling EM radiation having a second coupling frequency and a second coupling phase, wherein each of the probe frequency, the first coupling frequency, and the second coupling frequency comprises at least one of an ultraviolet (UV), a visible, or a near-infrared (NIR) frequency, and wherein the EM radiation of the plurality of optical frequencies is configured to excite the plurality of alkali atoms from a first quantum state to a plurality of Rydberg states comprising a quantum interferometric loop; and a detector configured to detect an electrically induced transparency (EIT) of the plurality of alkali atoms upon excitation of the alkali atoms by incident EM radiation comprising an incident EM frequency and an incident EM phase, wherein the EIT is indicative of the incident EM phase.

The techniques described in this disclosure may be implemented, at least in part, in hardware, software, firmware, or any combination thereof. For example, various aspects of the techniques may be implemented within one or more microprocessors, DSPs, ASICs, FPGAs, or any other equivalent integrated or discrete logic QRS circuitry, as well as any combinations of such components, embodied in external devices. The terms “processor” and “processing circuitry” may generally refer to any of the foregoing logic circuitry, alone or in combination with other logic circuitry, or any other equivalent circuitry, and alone or in combination with other digital or analog circuitry.

For aspects implemented in software, at least some of the functionality ascribed to the systems and devices described in this disclosure may be embodied as instructions on a computer-readable storage medium such as RAM, DRAM, SRAM, magnetic discs, optical discs, flash memories, or forms of EPROM or EEPROM. The instructions may be executed to support one or more aspects of the functionality described in this disclosure.

In addition, in some respects, the functionality described herein may be provided within dedicated hardware and/or software modules. Depiction of different features as modules or units is intended to highlight different functional aspects and does not necessarily imply that such modules or units must be realized by separate hardware or software components. Rather, functionality associated with one or more modules or units may be performed by separate hardware or software components or integrated within common or separate hardware or software components. Also, the techniques may be fully implemented in one or more circuits or logic elements.

1. A method comprising:
detecting, by an atomic receiver, incident electromagnetic (EM) radiation comprising an incident EM frequency and an incident EM phase; and
generating, by the atomic receiver and based on the detected incident EM radiation, a signal indicative of the incident EM phase, wherein the atomic receiver generates the signal without the use of a local oscillator.

2. The method of claim 1, wherein detecting the incident EM radiation comprises:
exciting, via EM radiation, a plurality of alkali atoms from a first quantum state to a plurality of Rydberg states comprising a quantum interferometric loop, wherein the EM radiation comprises:
a probe EM radiation having a probe frequency;
a first coupling EM radiation having a first coupling frequency and a first coupling phase; and
a second coupling EM radiation having a second coupling frequency and a second coupling phase,
detecting, via the probe EM radiation, an interferometric response of the plurality of alkali atoms upon excitation of the alkali atoms by the incident EM radiation, wherein the interferometric response is indicative of the incident EM phase,
wherein generating the signal comprises generating the signal based on the interferometric response; and
outputting the signal.

3. The method of claim 2, wherein the first quantum state is a ground state, and wherein the incident EM frequency completes the interferometric loop.

4. The method of claim 2, wherein the interferometric response is a first interferometric response, wherein the signal comprises a first signal, wherein the EM radiation further comprises a control EM radiation having a control frequency and a control phase,
the method further comprising:
changing the phase of at least one of the first coupling phase, the second coupling phase, or the control phase;
detecting, via the probe EM radiation, a second interferometric response of the plurality of alkali atoms upon excitation of the alkali atoms by the incident EM radiation, wherein the second interferometric response is indicative of the incident EM phase;
generating, by the atomic receiver and based on the second interferometric response, a second signal indicative of the incident EM phase, wherein the atomic receiver generates the second signal without the use of a local oscillator; and
outputting the second signal.

5. The method of claim 4, wherein two or more of the first coupling phase, the second coupling phase, and the third coupling phase are phase-locked relative to each other.

6. The method of claim 4,
wherein each of the probe frequency, the first coupling frequency, the second coupling frequency, and the control frequency comprises at least one of an ultraviolet (UV), a visible, or a near-infrared (NIR) frequency, and
wherein the incident EM frequency comprises a radio frequency.

7. The method of claim 6, wherein the radio frequency comprises a frequency between 10 megahertz and 1 terahertz.

8. The method of claim 2, wherein the signal based on the interferometric response comprises an in-phase signal and a quadrature signal.

9. The method of claim 2, the method further comprising:
determining, based on the signal, the first coupling phase, and the second coupling phase, the incident EM phase,
wherein determining the incident EM phase is not limited to any range of phase values.

10. The method of claim 9, wherein determining the incident EM phase comprises demodulating the in-phase signal and the quadrature signal without using a radio frequency local oscillator, wherein demodulating the in-phase signal and the quadrature signal is based on the signal, the first coupling phase and the second coupling phase.

11. The method of claim 2, wherein the interferometric response of the plurality of alkali atoms upon excitation of the alkali atoms by incident EM radiation comprises an electromagnetically induced transparency of the plurality of alkali atoms.

12. The method of claim 1, wherein the atomic receiver comprises an electrically small receiver.

13. A sensing system comprising an atomic receiver configured to detect an incident EM phase of incident electromagnetic (EM) radiation without the use of a local oscillator.

14. The sensing system of claim 13, wherein the sensing system is configured to determine a phase value of the detected incident EM phase without limiting the phase value to any range of phase values.

15. The sensing system of claim 13, wherein the atomic receiver comprises:
a vapor cell including a plurality of alkali atoms;
a preparation system configured to excite the plurality of alkali atoms from a first quantum state to a plurality of Rydberg states comprising a quantum interferometric loop,
wherein the preparation system is configured to direct EM radiation of a plurality of frequencies into the vapor cell and incident on the vapor of alkali atoms, the preparation system comprising:
a probe EM radiation having a probe frequency;
a first coupling EM radiation having a first coupling frequency and a first coupling phase; and
a second coupling EM radiation having a second coupling frequency and a second coupling phase; and
a detector configured to detect an interferometric response of the plurality of alkali atoms upon excitation of the alkali atoms by the incident EM radiation comprising an incident EM frequency and the incident EM phase, wherein the detector is configured to output a signal proportional to the interferometric response of the plurality of alkali atoms,
wherein the sensing system further comprises:
processing circuitry configured to determine, based on the signal, the incident EM phase.

16. The system of claim 15, wherein the first quantum state is a ground state, and wherein the incident EM frequency completes the interferometric loop.

17. The system of claim 15, wherein the interferometric response is a first interferometric response, wherein the signal comprises a first signal,
wherein the preparation system further comprises a control EM radiation having a control frequency and a control phase,
wherein the preparation system is further configured to change the phase of at least one of the first coupling phase, the second coupling phase, or the control phase,
wherein the detector is further configured to:
detect a second interferometric response of the plurality of alkali atoms upon excitation of the alkali atoms by the incident EM radiation, wherein the second interferometric response is indicative of the incident EM phase; and
output, a second signal proportional to the second interferometric response of the plurality of alkali atoms, and
wherein the processing circuitry configured to determine, based on the second signal, the incident EM phase.

18. (canceled)

19. The system of claim 17,
wherein each of the probe frequency, the first coupling frequency, the second coupling frequency, and the control frequency comprises at least one of an ultraviolet (UV), a visible, or a near-infrared (NIR) frequency, and
wherein the incident EM frequency comprises a radio frequency.

20. (canceled)

21. The system of claim 15,
wherein the signal proportional to the interferometric response of the plurality of alkali atoms comprises an in-phase signal and a quadrature signal,
wherein to determine the incident EM phase the processing circuitry is further configured to:
demodulate the in-phase signal and the quadrature signal without using a radio frequency local oscillator,
wherein demodulating the in-phase signal and the quadrature signal is based on the signal, the first coupling phase, and the second coupling phase.

22. A sensing system, comprising:
a vapor cell including a plurality of alkali atoms;
a preparation system configured to direct optical electromagnetic (EM) radiation of a plurality of optical frequencies into the vapor cell and incident on the plurality of alkali atoms, the preparation system comprising:
a probe electromagnetic (EM) radiation having a probe frequency;
a first coupling EM radiation having a first coupling frequency and a first coupling phase; and
a second coupling EM radiation having a second coupling frequency and a second coupling phase,
wherein each of the probe frequency, the first coupling frequency, and the second coupling frequency comprises at least one of an ultraviolet (UV), a visible, or a near-infrared (NIR) frequency, and
wherein the EM radiation of the plurality of optical frequencies is configured to excite the plurality of alkali atoms from a first quantum state to a plurality of Rydberg states comprising a quantum interferometric loop; and
a detector configured to detect an electrically induced transparency (EIT) of the plurality of alkali atoms upon excitation of the alkali atoms by incident EM radiation comprising an incident EM frequency and an incident EM phase, wherein the EIT is indicative of the incident EM phase.
